(19) United States
(12) Patent Application Publication
(10) Pub. No.: US 2003/0116774 A1
(43) Pub. Date: Jun. 26, 2003

(54) Nitride-based semiconductor light-emitting device and manufacturing method thereof

(76) Inventors: Kensaku Yamamoto, Mihara-shi (JP); Norikatsu Koide, Nagoya-shi (JP)

Correspondence Address: Madeline I. Johnston, Morrison & Foerster LLP, 755 Page Mill Road, Palo Alto, CA, 94304-1018, US

(21) Appl. No.: 10/310,463

(22) Filed: Dec. 4, 2002

(30) Foreign Application Priority Data
Dec. 7, 2001 (JP) 2001-374240

(51) Int. Cl. H01L 33/00; H01L 21/00

(52) U.S. Cl. 257/94; 257/103; 438/44; 438/46; 438/47

(57) ABSTRACT

A nitride-based semiconductor light-emitting device includes: a conductive semiconductor substrate having first and second main surfaces; a high resistant or insulative intermediate layer formed on the first main surface of the substrate; a plurality of nitride semiconductor layers of AlₓB_{y}In_{z}Ga_{1-x-y-z}N (0<x≦1, 0≦y<1, 0≦z≦1, x+y+z=1) formed on the intermediate layer, the nitride semiconductor layers including at least one first conductivity type layer, a light-emitting layer and at least one second conductivity type layer sequentially stacked on the intermediate layer; a metal film penetrating through or detouring around the intermediate layer to connect the first conductivity type layer in contact with the intermediate layer to the conductive substrate; a first electrode formed on the second conductivity type layer; and a second electrode formed on the second main surface of the substrate. Voltage drop in the intermediate layer is avoided by the metal film, so that an operating voltage is reduced.

### BACKGROUND OF THE INVENTION

1. Field of the Invention

The present invention relates to a light-emitting device utilizing nitride-based semiconductor of III-V group compound, and more particularly to improvement in a nitride-based semiconductor light-emitting device having current-introducing electrodes provided on both main surface sides of a conductive substrate.

2. Description of the Background Art

In a conventional gallium-nitride-based semiconductor light-emitting device, an insulative substrate such as a sapphire substrate has been used. With such an insulative substrate, it is impossible to introduce a current to a light-emitting layer through the insulative substrate. Thus, in general, electrodes for p type and n type semiconductor are both formed on the same main surface side of the substrate on which semiconductor layers are stacked. In this case, it is necessary to secure a region for forming the both electrodes on one side of the substrate. This results in a less number of light-emitting devices formed on a unit area of the substrate, compared to the case where each electrode is formed on a respective main surface side of the substrate. In addition, the sapphire substrate is expensive as well as hard and thus poor in workability. Under these circumstances, it has been studied to form a gallium-nitride-based semiconductor light-emitting device on a conductive Si substrate.

However, although the Si substrate may be conductive, AlN, AlGaN or the like used as an intermediate layer (buffer layer) for epitaxial growth of the gallium-nitride-based semiconductor layer has a high resistivity and serves nearly as an insulator, compared to the conductive Si substrate and an n type GaN layer. Thus, in the case where the electrodes for a p type and for an n type are provided on the front side and the rear side of the Si substrate, the intermediate layer will cause a large voltage drop, and an operating voltage of the light-emitting device will increase.

FIG. 13 is a schematic cross sectional view of a nitride-based semiconductor light-emitting device disclosed in Japanese Patent Laying-Open No. 11-40850. This nitride-based semiconductor light-emitting device includes an n type intermediate layer 702, an n type superlattice layer 703 for relaxing strain, an n type high carrier concentration layer 704, a multiple quantum well light-emitting layer 705, a p type clad layer 706, a p type contact layer 707 and a light-transmitting electrode 709 which are sequentially stacked on a front surface of an n type Si substrate 701, and also includes an electrode 708 formed on a rear surface of the substrate 701. That is, electrode 709 for a p type is formed on the front side of the conductive Si substrate 701, while electrode 708 for an n type is formed on the rear side.

In the light-emitting device disclosed in Japanese Patent Laying-Open No. 11-40850, intermediate layer 702 on n type Si substrate 701 is formed of Si-doped Al_{0.15}Ga_{0.85}N:Si. This Al_{0.15}Ga_{0.85}N:Si intermediate layer 702, however, has a high resistivity compared to n type Si substrate 701 and n type GaN layer 704 within the structure of the light-emitting device. Thus, when current is introduced from electrodes 708, 709 on both sides of substrate 701 into light-emitting layer 705, a voltage drop occurs in intermediate layer 702, leading to an increase of operating voltage of the light-emitting device.

### SUMMARY OF THE INVENTION

In view of the aforementioned prior art state, an object of the present invention is to reduce an operating voltage of a nitride-based semiconductor light-emitting device having current-introducing electrodes formed on both main surface sides of a conductive substrate.

According to the present invention, a nitride-based semiconductor light-emitting device includes a conductive semiconductor substrate having first and second main surfaces, a high-resistant or insulative intermediate layer formed on the first main surface of the substrate, and a plurality of nitride semiconductor layers of AlₓB_{y}In_{z}Ga_{1-x-y-z}N (0<x≦1, 0≦y<1, 0≦z≦1, x+y+z=1) formed on the intermediate layer. The plurality of nitride semiconductor layers include at least one first conductivity type layer, a light-emitting layer and at least one second conductivity type layer which are sequentially stacked on the intermediate layer. The nitride-based semiconductor light-emitting device also includes a metal film penetrating through or detouring around the intermediate layer to connect the first conductivity type layer in contact with the intermediate layer to the conductive substrate, and further includes a first electrode formed on the second conductivity type layer and a second electrode formed on the second main surface of the conductive substrate. A voltage drop in the intermediate layer is avoided by the metal film, so that an operating voltage is reduced.

AlₓB_{y}In_{z}Ga_{1-x-y-z}N (0<x≦1, 0≦y<1, 0≦z≦1, x+y+z=1) may also be used for the intermediate layer. The intermediate layer preferably has a thickness of at least 10 nm.

Preferably, the metal film is in ohmic contact with both the conductive substrate and the first conductivity type layer contacting the intermediate layer. The metal film preferably has a melting point higher than 900° C. At least one selected from a group consisting of Sc, Ti, V, Cr, Mn, Cu, Y, Nb, Mo, Ru, Hf, Ta and W may be used for the metal film.

The nitride-based semiconductor light-emitting device may further include a dielectric film to prevent the metal film from contacting the light-emitting layer and the second conductivity type layer. At least one selected from a group consisting of SiO₂, Si₃N₄, Sc₂O₃, Zr₂O₃, Y₂O₃, Gd₂O₃, La₂O₃, Ta₂O₅, ZrO₂, LaAlO₃, ZrTiO₄, and HfO₂ may be used for the dielectric film.

The metal film may be formed in a striped pattern. The metal film stripes may be arranged along one direction or at least two different directions with an interval in a range from 1 μm to 500 μm.

The light-emitting layer is preferably formed in a region partitioned by a partitioning stripe having a width of at least 1 μm formed on the substrate. A dielectric film may be formed as the partitioning stripe, and at least one selected from a group consisting of SiO₂, Si₃N₄, Sc₂O₃, Zr₂O₃, Y₂O₃, Gd₂O₃, La₂O₃, Ta₂O₅, ZrO₂, LaAlO₃, ZrTiO₄ and HfO₂ may be used for the dielectric film. Alternatively, at least one metal selected from a group consisting of Sc, Ti, V, Cr, Mn, Cu, Y, Nb, Mo, Ru, Hf, Ta and W may be used for the partitioning stripe.

Si, ZnO or GaP including a dopant may be used for the conductive semiconductor substrate.

A method for manufacturing the nitride-based semiconductor light-emitting device according to the present invention may include the steps of forming at least the intermediate layer on the conductive semiconductor substrate in a film-deposition system, taking out a wafer having at least the intermediate layer formed on the substrate temporarily to the atmosphere and forming an opening portion penetrating through the intermediate layer, forming the metal film in the opening portion, and introducing the wafer back to the film-deposition system and forming the plurality of nitride semiconductor layers.

Further, a method for manufacturing the nitride-based semiconductor light-emitting device may include the steps of forming the partitioning stripe of a dielectric film on the substrate, forming the intermediate layer, forming the plurality of nitride semiconductor layers, removing the partitioning stripe, forming an insulating film for preventing the light-emitting layer and the second conductivity type layer from contacting the metal film, and subsequently forming the metal film for connecting the first conductivity type layer to the conductive substrate through a side of the intermediate layer.

Still further, a method for manufacturing the nitride-based semiconductor light-emitting device may include the steps of removing, by first etching, a portion of the conductive substrate utilizing the intermediate layer as an etching stop layer; removing, by second etching, a portion of the intermediate layer exposed by the first etching; and forming the metal film connecting the first conductivity type layer to the conductive substrate via a region where the intermediate layer has been partly removed by the second etching.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A-1C and 2A-2B are schematic cross sectional views illustrating manufacturing steps of a light-emitting diode according to a first embodiment of the present invention.

FIGS. 3A-3C and 4 are schematic cross sectional views illustrating manufacturing steps of a light-emitting diode according to a second embodiment of the present invention.

FIGS. 5A-5D are schematic cross sectional views illustrating manufacturing steps that can replace the steps shown in FIGS. 3A-3C.

FIGS. 6A-6C and 7A-7B are schematic cross sectional views illustrating manufacturing steps of a light-emitting diode according to a third embodiment of the present invention.

FIGS. 8A-8B and 9A-9B are schematic cross sectional views illustrating manufacturing steps of a light-emitting diode according to a fourth embodiment of the present invention.

FIGS. 10A-10B and 11A-11B are schematic cross sectional views illustrating manufacturing steps of a light-emitting diode according to a fifth embodiment of the present invention.

FIG. 12 is a graph showing characteristics related to operating voltage and current in the light-emitting diodes of the respective embodiments.

FIG. 13 is a schematic cross sectional view illustrating a conventional light-emitting diode.

### DESCRIPTION OF THE PREFERRED EMBODIMENTS

First Embodiment

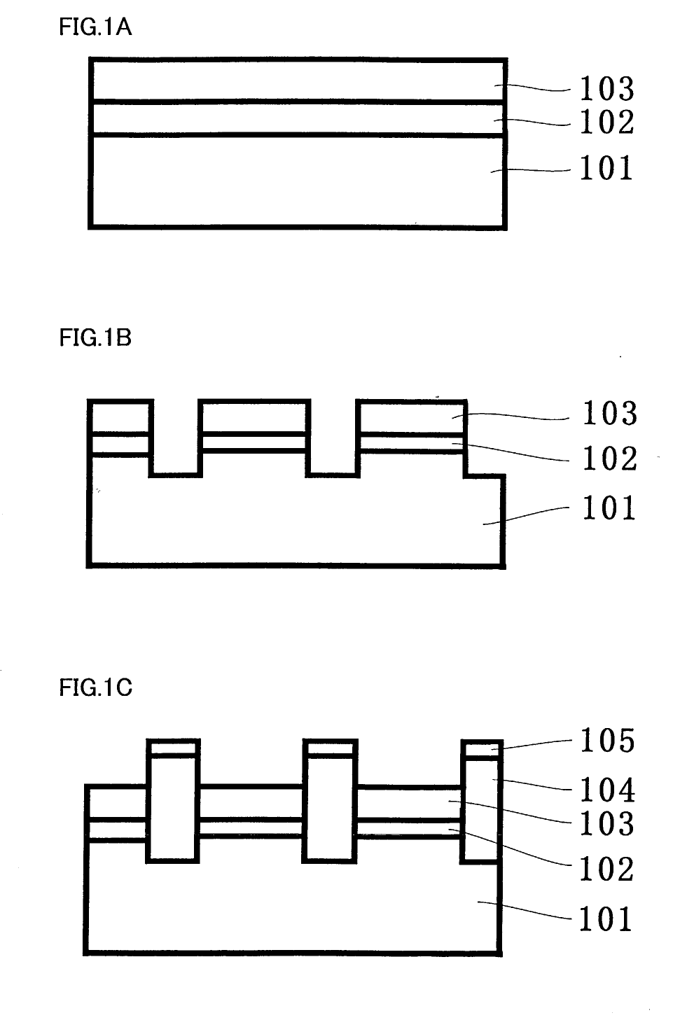

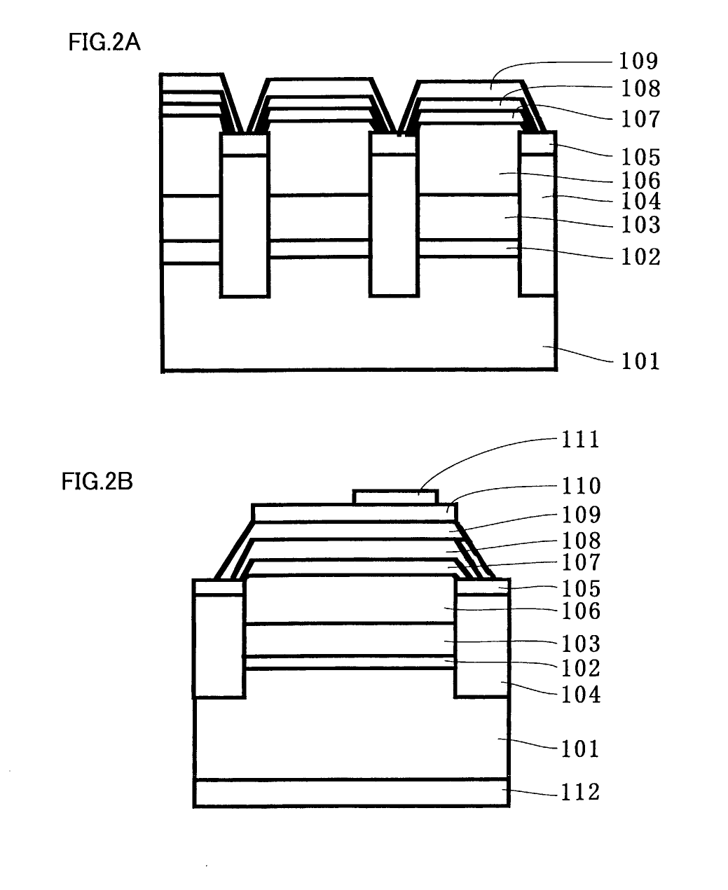

Manufacturing steps of a nitride-based semiconductor light-emitting device according to a first embodiment of the present invention are illustrated in schematic cross sectional views of FIGS. 1A-1C and 2A-2B. Herein, the accompanying drawings are not to scale, with dimensional relationships of thickness, width and the others being changed as appropriate for the sake of clarity and simplicity of the drawings.

Referring to FIG. 1A, an n type Si substrate 101 cleaned with an aqueous solution of 5% hydrogen fluoride (HF) was employed. The Si substrate had a main surface of crystallographic {111} plane. In a metal organic chemical vapor deposition (MOCVD) system, Si substrate 101 was mounted to a susceptor, and baked at 1100° C. in an H₂ atmosphere. Thereafter, at the same substrate temperature and using H₂ as a carrier gas, trimethyl aluminum (TMA) and ammonia (NH₃) were used to form an AlN intermediate layer 102 to a thickness of at least 10 nm, and trimethyl gallium (TMG) and NH₃ were used to form an n type GaN layer 103 of 500 nm thickness.

Next, the wafer shown in FIG. 1A was taken out to the atmosphere. As shown in FIG. 1B, a trench for formation of a metal film was formed by photolithography, in parallel with a crystallographic <1-10> direction of Si substrate 101. At this time, reactive ion etching (RIE) was utilized to form the trench having a depth reaching Si substrate 101.

Thereafter, as shown in FIG. 1C, a tungsten (W) film 104 of 800 nm thickness was formed on the trench by sputtering or the like. A SiO₂ film 105 of 4 nm thickness was formed on W film 104 to prevent a short-circuit of the metal film with an active layer and a p type semiconductor layer included in the light-emitting device. The total thickness of W film 104 and SiO₂ film 105 was made greater than a depth from the surface of n type GaN layer 103 to the bottom of the trench formed by RIE. The trench was made to have a width of 150 μm, and an interval between the trenches was set to 200 μm.

Further, in FIG. 2A, the substrate temperature was rapidly increased to 1100° C. again in the MOCVD system, and TMG and NH₃ were used to form an n type GaN layer 106 of 300 nm thickness. At this time, n type GaN layer 106 was deposited to have a thickness sufficiently covering the edge portion of SiO₂ film 105 formed above the trench. Thereafter, at the substrate temperature of 750° C., trimethyl indium (TMI), TMG and NH₃ were used to form an MQW (multiple quantum well) active layer 107 having four pairs of In_{0.08}Ga_{0.92}N well layers and GaN barrier layers stacked one on another. Next, at the substrate temperature of 1100° C., TMG, NH₃ and cyclopentadienyl magnesium (Cp₂Mg) as a dopant were used to form a Mg-doped p type Al_{0.15}Ga_{0.85}N clad layer 108. Subsequently, at the same substrate temperature, TMG, NH₃ and Cp₂Mg were used to form a Mg-doped p type GaN contact layer 109.

Next, the wafer shown in FIG. 2A was taken out to the atmosphere and, as shown in FIG. 2B, a Pd light-transmitting electrode 110 and an Au pad electrode 111 were formed on p type GaN contact layer 109 by evaporation, and an n type electrode 112 was formed on the rear side of Si substrate 101 by evaporation. Thereafter, a SiO₂ dielectric film (not shown) was formed to protect the electrodes and to cover the plurality of semiconductor layers. In FIG. 2B, only a region corresponding to one light-emitting device chip in the wafer is shown.

Thereafter, the wafer was divided with a scribing or dicing device into individual nitride-based semiconductor light-emitting device chips each in a rectangular form having a side passing through the trench in parallel with the <1-10> direction described above and another side perpendicular thereto.

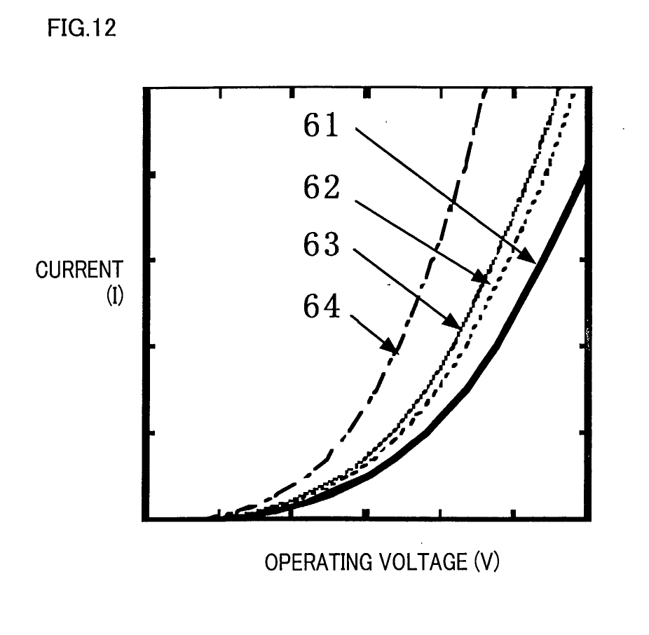

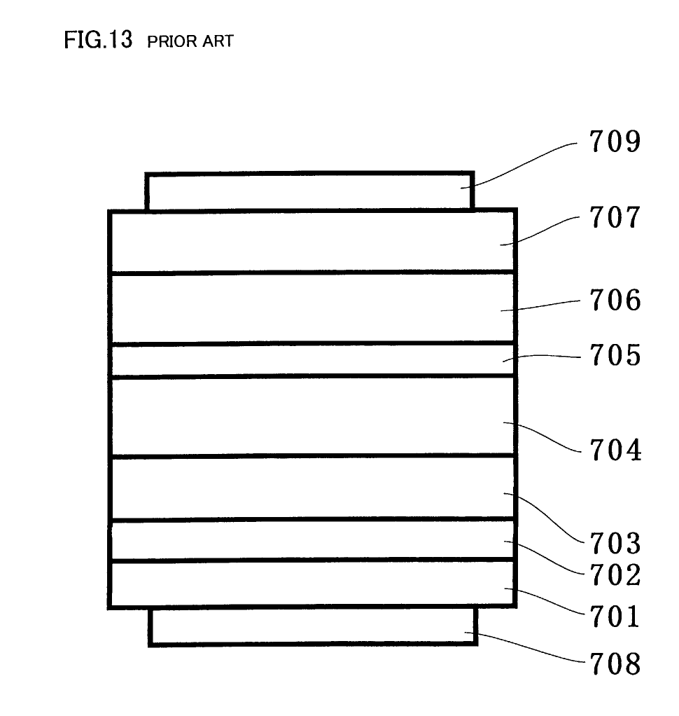

FIG. 12 is a graph showing characteristics related to operating voltage and current (hereinafter, also referred to as the “current to operating voltage characteristics”) in the nitride-based semiconductor light-emitting devices. In this graph, a curve 61 represents the characteristic of the light-emitting device according to Japanese Patent Laying-Open No. 11-40850. A curve 62 represents the characteristic of the light-emitting device according to the first embodiment.

As seen from FIG. 12, the light-emitting device of the first embodiment operates with a voltage lower than in the conventional case, and is improved in the current to operating voltage characteristic. In the conventional case, when the electrodes are formed on both sides of the Si substrate, current introduced from the outside of the light-emitting device has to pass through the intermediate layer of high resistivity. With the light-emitting device of the first embodiment, however, the externally introduced current can pass through the metal film instead of the intermediate layer and thus a voltage drop due to the high resistant intermediate layer is avoided, realizing a reduced operating voltage.

It is conventionally known that, when W and Si in contact with each other are subjected to heat treatment at high temperature, silicide WSi₂ will be produced at the interface. Silicide used as an interconnection material in the LSI (large scale integrated circuit) has a relatively high resistivity when treated at high temperature. In the first embodiment, W film 104 in contact with Si substrate 101 is exposed to a high temperature, and thus silicide may be produced at least at their interface. However, the scale of the light-emitting device is sufficiently large compared to that of the LSI, so that resistivity of the silicide hardly affects the operating voltage of the light-emitting device.

In the first embodiment, the interval between W film stripes 104 was 200 μm. As a result of further studies, however, it has been confirmed that a light-emitting device having the structure of the first embodiment and actually capable of emitting light can be formed if the interval of the W film stripes is at least 10 μm.

Second Embodiment

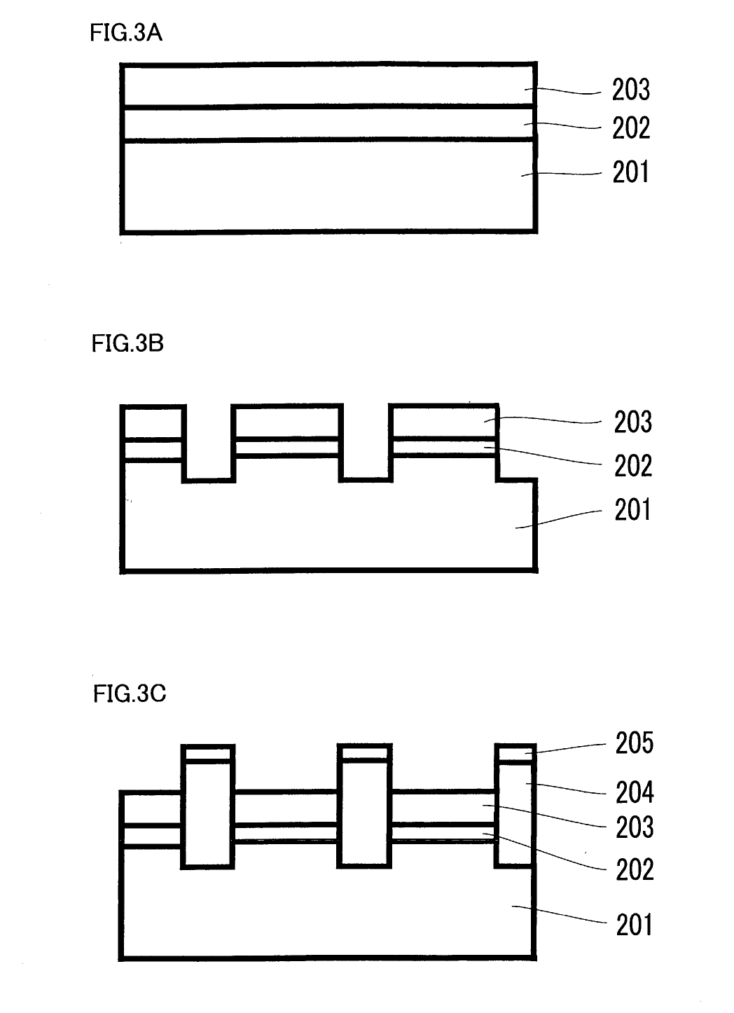

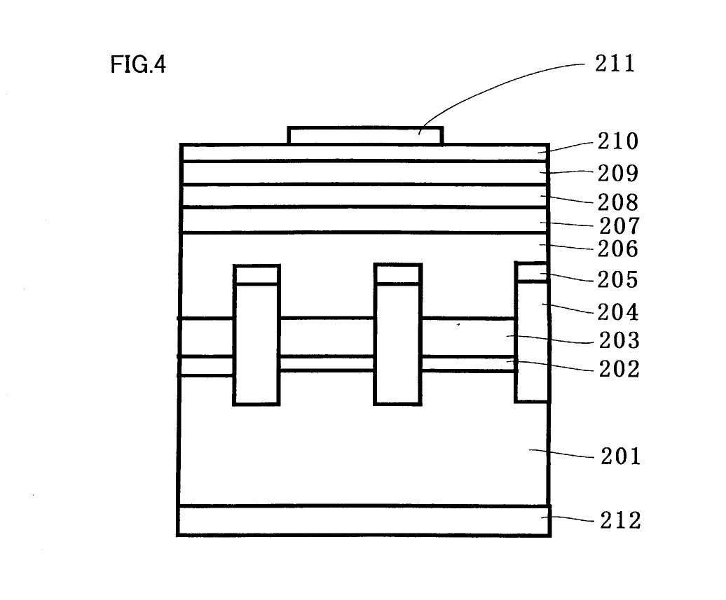

Manufacturing steps of a nitride-based semiconductor light-emitting device according to a second embodiment of the present invention are illustrated in schematic cross sectional views of FIGS. 3A-3C and 4. In FIG. 3A, a {111} Si substrate 201 having been cleaned with a 5% HF aqueous solution was mounted to a susceptor in a MOCVD system, and baked at 1100° C. in the H₂ atmosphere. Thereafter, at the same substrate temperature, using H₂ as a carrier gas, TMA and NH₃ were used to form an AlN intermediate layer 202 to a thickness of at least 10 nm, and TMG and NH₃ were used to form an n type GaN layer 203 of 500 nm thickness. Thereafter, the wafer shown in FIG. 3A was taken out to the atmosphere. A SiO₂ mask stripe (not shown) was formed in parallel with a <1-10> direction of the Si substrate, to etch a region in which a metal film is brought to contact with substrate 201.

Thereafter, as shown in FIG. 3B, a mixed solution of NH₃, HF and CH₃COOH was used to form a trench by etching to a depth reaching Si substrate 201.

Subsequently, as shown in FIG. 3C, a W film 204 of 800 nm thickness was formed by sputtering or the like, and a SiO₂ film 205 of 4 nm thickness was formed thereon. At this time, W film 204 was made to have a thickness greater than a depth from the surface of n type GaN layer 203 to the bottom of the trench formed by RIE. The width of the trench was 1 μm, and the interval between the trenches was 5 μm.

Thereafter, in FIG. 4, the substrate temperature was rapidly increased to 1100° C. again in the MOCVD system. TMG and NH₃ were used to form an n type GaN layer 206 of 4 μm thickness. At this time, n type GaN layer 206 was deposited to a thickness completely covering SiO₂ film 205. Subsequently, at the substrate temperature of 750° C., TMI, TMG and NH₃ were used to form an MQW active layer 207 including four pairs of In_{0.08}Ga_{0.92}N well layers and GaN barrier layers. Next, at the substrate temperature of 1100° C., TMG, NH₃ and Cp₂Mg as a dopant were used to form a Mg-doped p type Al_{0.15}Ga_{0.85}N clad layer 208. Subsequently, at the same substrate temperature, TMG, NH₃ and Cp₂Mg were used to form a Mg-doped p type GaN contact layer 209.

Thereafter, the wafer was taken out to the atmosphere, and a Pd light-transmitting electrode 210 and an Au pad electrode 211 were formed sequentially by evaporation, and an n type electrode 212 was formed on the rear side of Si substrate 201 by evaporation. Next, a SiO₂ dielectric film (not shown) was formed to protect the electrodes and to cover the plurality of semiconductor layers.

Thereafter, the wafer was divided with a scribing or dicing device into individual rectangular nitride-based semiconductor light-emitting device chips each having a side in parallel with the <1-10> direction of the Si substrate and another side perpendicular thereto.

In FIG. 12, the characteristic related to operating voltage and current in the light-emitting device of the second embodiment is shown as a curve 63. According to FIG. 12, the light-emitting device of the second embodiment is improved in the current to operating voltage characteristic compared to the first embodiment (curve 62). This presumably is because, with n type GaN layer 206 formed thickly on metal film 204, dislocation density in the vicinity of active layer 207 has been reduced to improve crystallinity, thereby further improving the current to operating voltage characteristic of the second embodiment compared to that of the first embodiment.

In the second embodiment, the interval between W film stripes 204 was 5 μm. As a result of further studies, however, it has been found that the light-emitting device having the structure of the second embodiment and actually capable of emitting light can be formed if the interval of the W film stripes is at least 1 μm and at most 10 μm.

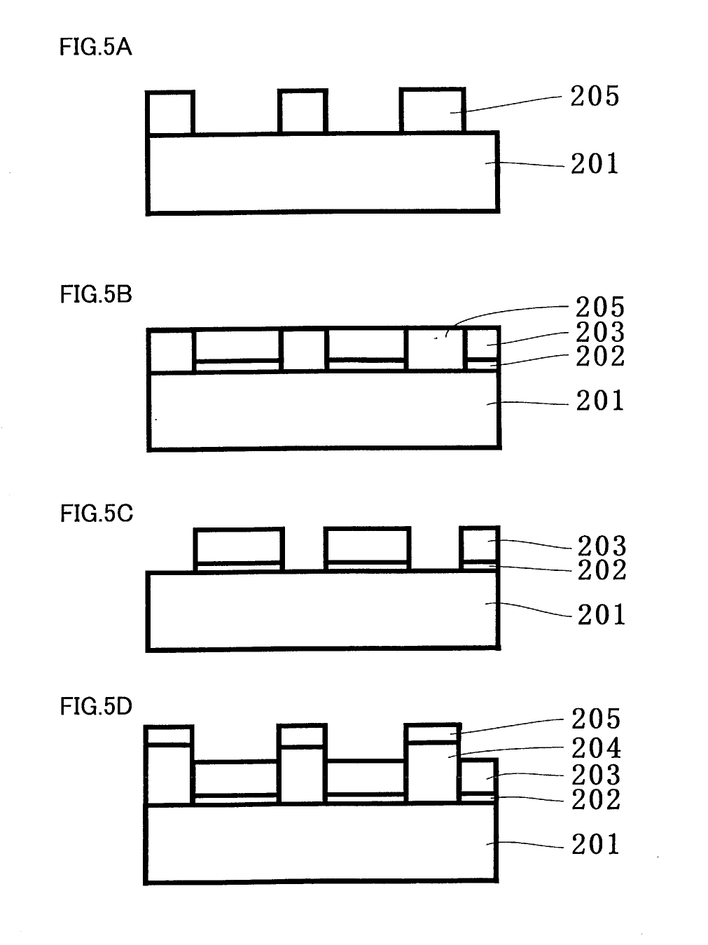

The light-emitting device shown in FIG. 4 can also be formed through the manufacturing steps shown in FIGS. 5A-5D instead of those in FIGS. 3A-3C. According to the steps shown in FIGS. 5A-5D, a SiO₂ mask stripe 205 was formed on a {111} Si substrate 201 cleaned with a 5% HF aqueous solution, as shown in FIG. 5A. Next, as shown in FIG. 5B, an AlN intermediate layer 202 and an n type GaN layer 203 thereon were formed by MOCVD. The wafer shown in FIG. 5B was taken out to the atmosphere and as shown in FIG. 5C, a trench was formed by removing SiO₂ mask stripe 205. Thereafter, as shown in FIG. 5D, photolithography was utilized to form a W film 204 on the trench by evaporation and then a SiO₂ film 205 was formed thereon by sputtering. Thereafter, the step as explained in conjunction with FIG. 4 was carried out, and a light-emitting device as shown in FIG. 4 was obtained with its characteristic related to operating voltage and current similarly improved.

Third Embodiment

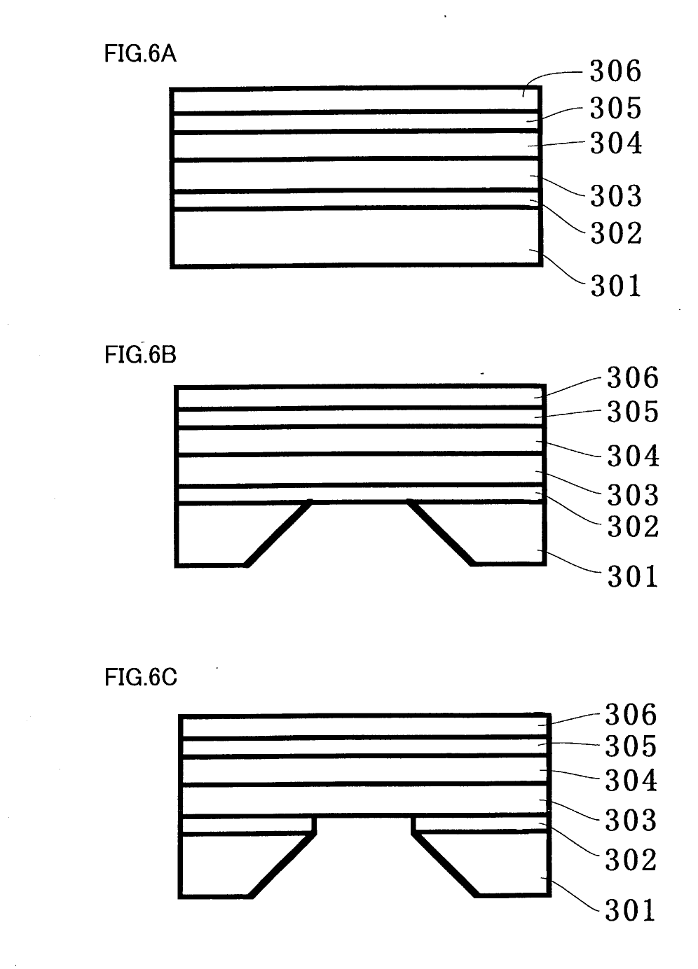

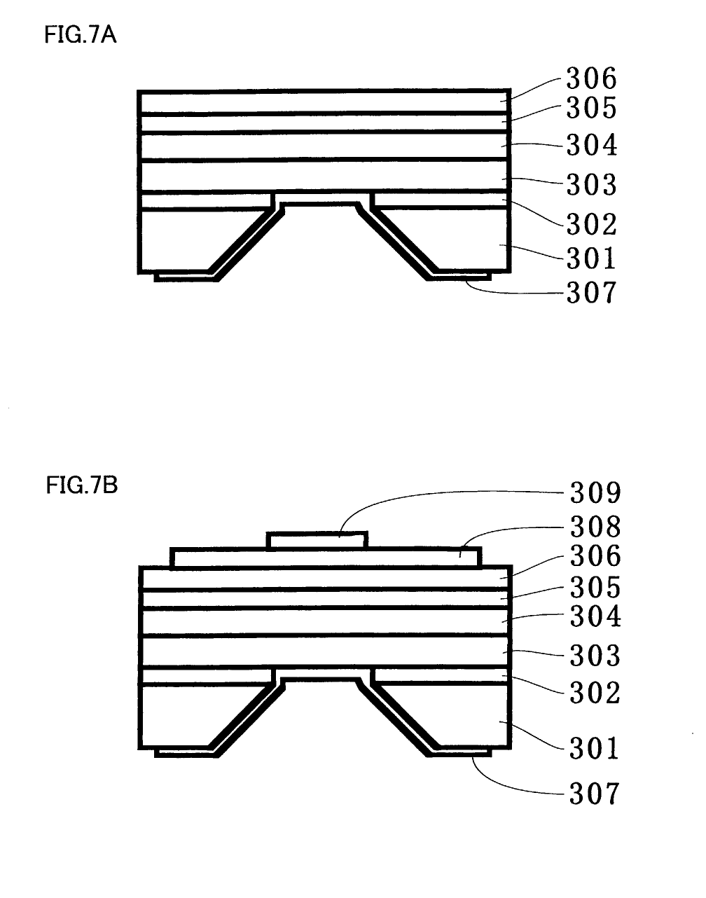

Manufacturing steps of a nitride-based semiconductor light-emitting device according to a third embodiment of the present invention are illustrated in schematic cross sectional views of FIGS. 6A-6C and 7A-7B. In FIG. 6A, a {111} Si substrate 301 cleaned with a 5% HF aqueous solution was mounted to a susceptor in a MOCVD system, and baked at 1100° C. in the H₂ atmosphere. Thereafter, at the same substrate temperature, using H₂ as a carrier gas, TMA and NH₃ were used to form an AlN intermediate layer 302 to a thickness of at least 10 nm, and TMG and NH₃ were used to form an n type GaN layer 303 of 2 μm thickness. Thereafter, at the substrate temperature of 750° C., TMI, TMG and NH₃ were used to form an MQW active layer 304 including four pairs of In_{0.08}Ga_{0.92}N well layers and GaN barrier layers. Next, at the substrate temperature of 1100° C., TMG, NH₃ and Cp₂Mg as a dopant were used to form a Mg-doped p type Al_{0.15}Ga_{0.85}N clad layer 305. Subsequently, at the same substrate temperature, TMG, NH₃ and Cp₂Mg were used to form a Mg-doped p type GaN contact layer 306.

Thereafter, a SiO₂ mask (not shown) for formation of an opening portion in Si substrate 301 was formed on the rear side of the substrate. With the presence of the mask, a mixed solution of NH₃, HF and CH₃COOH was used to etch Si substrate 301 to form the opening portion in the substrate, as shown in FIG. 6B. Here, in contrast to a sapphire substrate or a SiC substrate for which etching itself is difficult, Si substrate 301 was etched while AlN intermediate layer 302 was serving as an etching-stop layer. Thereafter, as shown in FIG. 6C, AlN intermediate layer 302 was etched by RIE.

Subsequently, as shown in FIG. 7A, a layered film of Ti and Al stacked in this order was formed by evaporation as an n type electrode 307 contacting conductive Si substrate 301, AlN intermediate layer 302 and n type GaN layer 303.

Thereafter, as shown in FIG. 7B, a Pd light-transmitting electrode 308 was formed on p type GaN contact layer 306, and an Au pad electrode 309 was formed thereon. A SiO₂ dielectric film (not shown) was further formed to protect the electrodes and to cover the plurality of semiconductor layers. Thereafter, the wafer was divided using a scribing or dicing device into individual nitride-based semiconductor light-emitting device chips.

In FIG. 12, the characteristic related to operating voltage and current of the light-emitting device of the third embodiment is shown as a curve 64. According to FIG. 12, the light-emitting device of the third embodiment is further improved in the current to operating voltage characteristic compared to the first embodiment (curve 62) and the second embodiment (curve 63). That is, in the light-emitting device of the third embodiment, metal film 307 serves to avoid not only the high resistivity of intermediate layer 302 but also the resistivity of Si substrate 301, so that resistivity of the light-emitting device is considerably reduced, and accordingly the operating voltage is further reduced compared to the first and second embodiments.

Fourth Embodiment

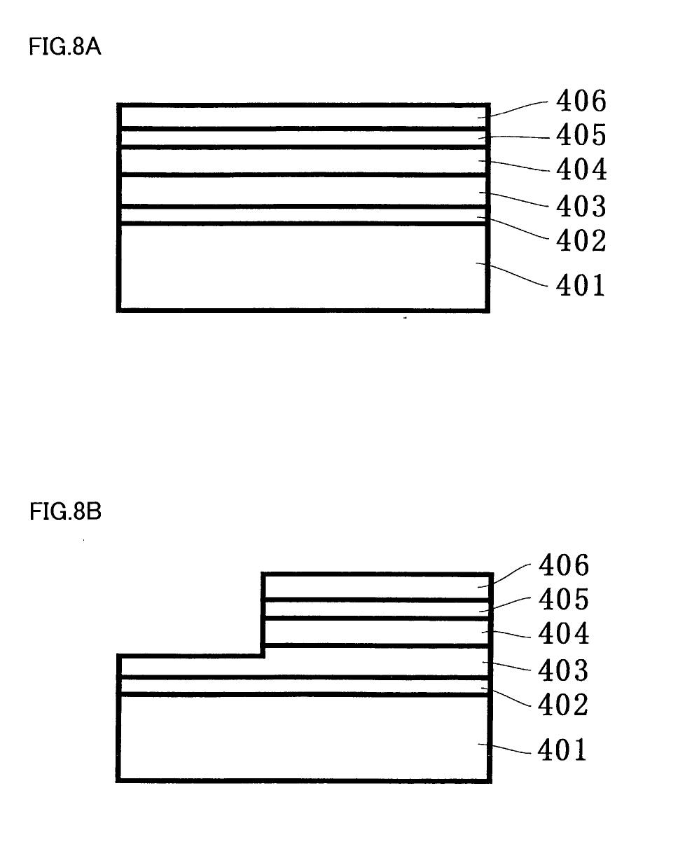

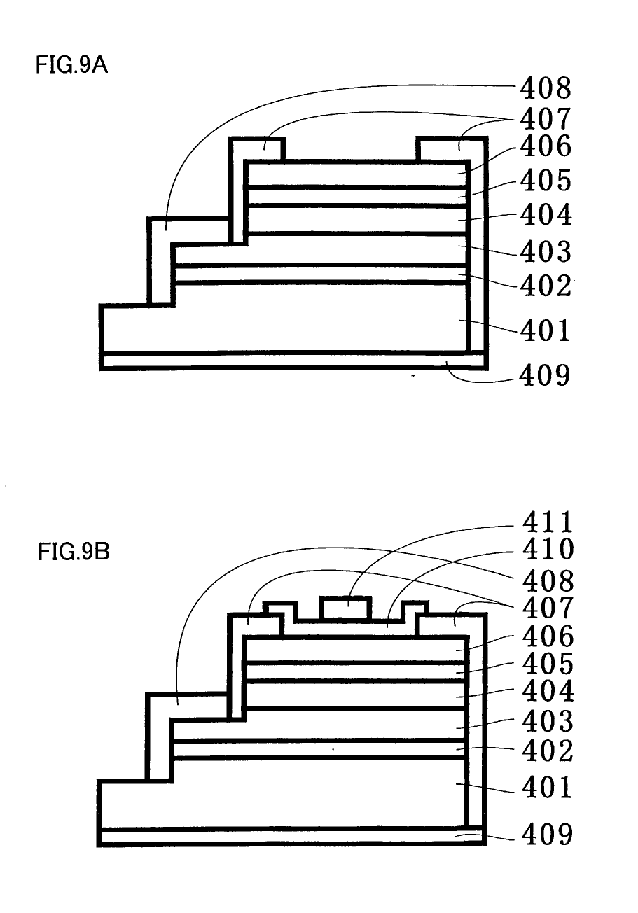

Manufacturing steps of a nitride-based semiconductor light-emitting device according to a fourth embodiment of the present invention are illustrated in schematic cross sectional views of FIGS. 8A-8B and 9A-9B. In FIG. 8A, a {111} Si substrate 401 cleaned with a 5% HF aqueous solution was mounted to a susceptor in a MOCVD system, and baked at 1100° C. in the H₂ atmosphere. Thereafter, using H₂ as a carrier gas at the same substrate temperature, TMA and NH₃ were used to form an AlN intermediate layer 402 to a thickness of at least 10 nm, and TMG and NH₃ were used to form an n type GaN layer 403 of 2 μm thickness. Thereafter, at the substrate temperature of 750° C., TMI, TMG and NH₃ were used to form an MQW active layer 404 including four pairs of In_{0.08}Ga_{0.92}N well layers and GaN barrier layers. Next, at the substrate temperature of 1100° C., TMG, NH₃ and Cp₂Mg as a dopant were used to form a Mg-doped p type Al_{0.15}Ga_{0.85}N clad layer 405. Subsequently, at the same substrate temperature, TMG, NH₃ and Cp₂Mg were used to form a Mg-doped p type GaN contact layer 406.

Thereafter, the wafer shown in FIG. 8A was taken out to the atmosphere and, as shown in FIG. 8B, a trench was formed by RIE from p type GaN contact layer 406 to reach n type GaN layer 403. At this time, an interval between the trenches was set to 200 μm for the sake of easier dividing of light-emitting device chips. FIG. 8B shows a region corresponding to only one light-emitting device chip delimited by the trench.

Thereafter, as shown in FIG. 9A, a SiO₂ film 407 was formed. Next, a trench was formed by photolithography from the exposed surface of n type GaN layer 403 to reach Si substrate 401. A metal film 408 was formed to connect n type GaN layer 403 to conductive Si substrate 401. Here, SiO₂ film 407 is provided to prevent metal film 408 from contacting active layer 404 and p type layers 405 and 406. Thereafter, a layered film of Ti/Al was deposited by evaporation to form an n type electrode 409.

Thereafter, as shown in FIG. 9B, a Pd light-transmitting electrode 410 and an Au pad electrode 411 thereon were formed. Next, a SiO₂ dielectric film (not shown) was formed to protect the electrodes and to cover the plurality of semiconductor layers. Thereafter, the wafer was divided with a scribing or dicing device into individual nitride-based semiconductor light-emitting device chips.

The characteristic related to operating voltage and current of the light-emitting device according to the fourth embodiment was identical to that of the first embodiment shown as curve 62 in FIG. 12. In the fourth embodiment, the interval between the trenches was set to 200 μm. However, the size of the light-emitting device chips can be changed by changing the trench interval to, e.g., 300 μm or 400 μm.

Fifth Embodiment

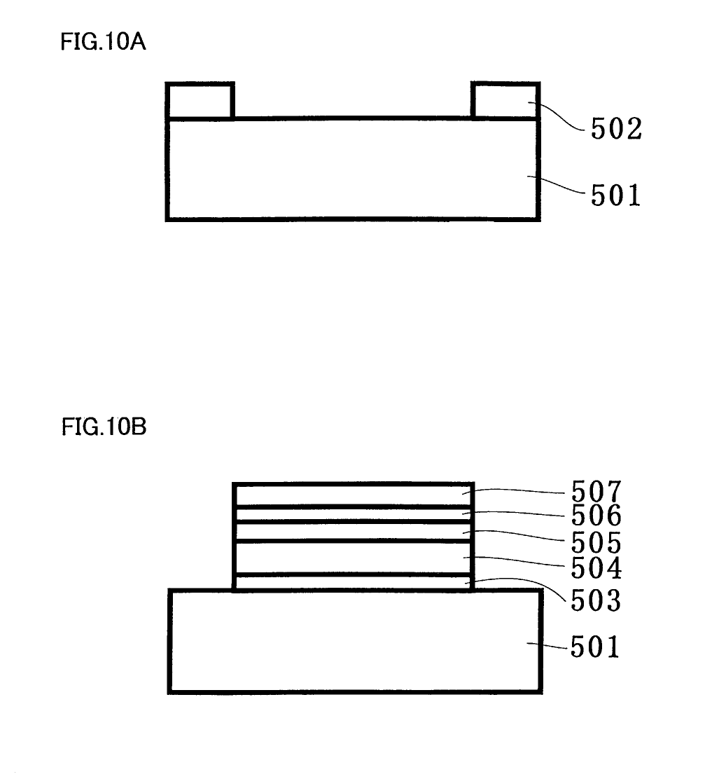

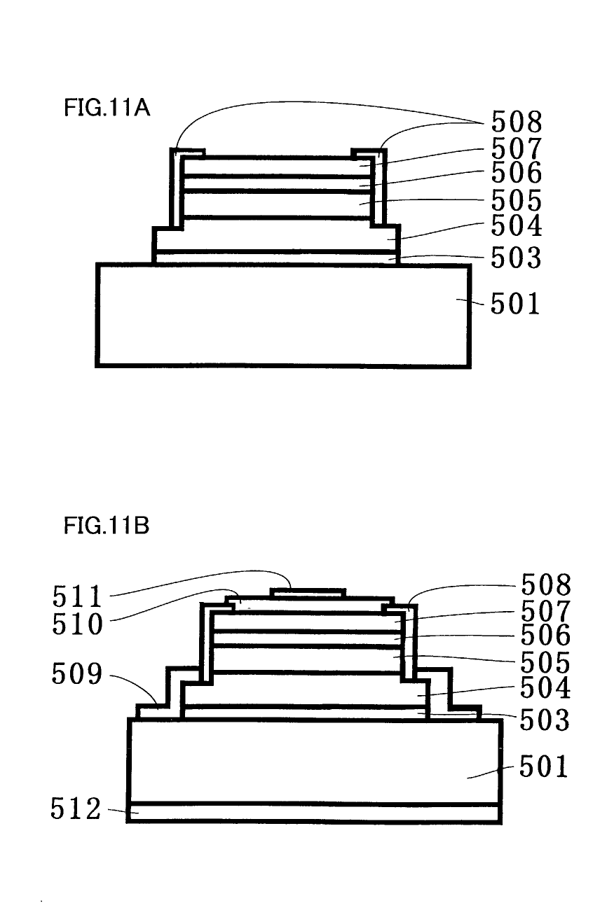

Manufacturing steps of a nitride-based semiconductor light-emitting device according to a fifth embodiment of the present invention are illustrated in schematic cross sectional views of FIGS. 10A-10B and 11A-11B. In order to form a light-emitting device within a 200-μm-square region on a {111} Si substrate 501 cleaned with a 5% HF aqueous solution, SiO₂ partitioning stripes 502 perpendicularly crossing one another were formed by photolithography and sputtering, as shown in FIG. 10A. At this time, the interval of the SiO₂ stripes was 200 μm, and the width of the stripe was 5 μm. FIG. 10A shows a region corresponding to only one light-emitting device chip.

In FIG. 10B after cleaning of the wafer of FIG. 10A, the wafer was mounted to a susceptor in a MOCVD device, and baked at 1100° C. in the H₂ atmosphere. Thereafter, using H₂ as the carrier gas at the same substrate temperature, TMA and NH₃ were used to form an AlN intermediate layer 503 to a thickness of at least 10 nm, and TMG and NH₃ were used to form an n type GaN layer 504 of 2 μm thickness. Thereafter, at the substrate temperature of 750° C., TMI, TMG and NH₃ were used to form an MQW active layer 505 including four pairs of In_{0.08}Ga_{0.92}N well layers and GaN barrier layers. Next, at the substrate temperature of 1100° C., TMG, NH₃ and Cp₂Mg as a dopant were used to form a Mg-doped p type Al_{0.15}Ga_{0.85}N clad layer 506. Subsequently, at the same substrate temperature, TMG, NH₃ and Cp₂Mg were used to form a Mg-doped p type GaN contact layer 507. Thereafter, the wafer was taken out to the atmosphere, and SiO₂ partitioning stripes 502 were removed with a 5% HF aqueous solution or the like.

Thereafter, as shown in FIG. 11A, portions of nitride semiconductor layers 504-507 were removed by photolithography and RIE, and a SiO₂ film 508 was formed by sputtering.

Thereafter, as shown in FIG. 11B, a metal film 509 of Ti/Al stacked layers was formed by photolithography and evaporation, to connect n type GaN layer 504 to conductive Si substrate 501. Here, SiO₂ film 508 is provided to prevent metal film 509 from contacting active layer 505 and p type layers 506 and 507. Thereafter, a Pd light-transmitting electrode 510 and an Au pad electrode 511 thereon were formed. An n type electrode 512 was formed on the rear side of Si substrate 501.

Next, a SiO₂ dielectric film (not shown) was formed to protect the electrodes and to cover the plurality of semiconductor layers. Thereafter, the wafer was divided with a scribing or dicing device into individual nitride-based semiconductor light-emitting device chips. The characteristic related to operating voltage and current of the light-emitting device according to the fifth embodiment was similar to that of the first embodiment shown as curve 62 in FIG. 12.

In the fifth embodiment, SiO₂ was used to form partitioning stripe 502. However, it may be formed of at least one dielectric material selected from a group consisting of Si₃N₄, Sc₂O₃, Zr₂O₃, Y₂O₃, Gd₂O₃, La₂O₃, Ta₂O₅, ZrO₂, LaAlO₃, ZrTiO₄ and HfO₂, or may be formed of at least one metal selected from a group consisting of Sc, Ti, V, Cr, Mn, Cu, Y, Nb, Mo, Ru, Hf and TaW. The partitioning stripe may also be formed using both the dielectric material and the metal as above.

In the first and second embodiments, W was used for metal films 104, 204. This is because W has a melting point much higher than the growth temperature of the GaN layer, and thus even if the AlₓB_{y}In_{z}Ga_{1-x-y-z}N (0<x≦1, 0≦y<1, 0≦z≦1, x+y+z=1) layer is grown after formation of the metal film, the metal film is unlikely to suffer influence of heat. As a result of further studies, it has been found that it is only needed to select a metal having a melting point higher than 900° C. that is higher than the growth temperature of the GaN layer. Accordingly, not limited to W, the metal film may be formed of at least one selected from a group consisting of Sc, Ti, V, Cr, Mn, Cu, Y, Nb, Mo, Ru, Hf and Ta.

In the first and second embodiments, SiO₂ was used to form the dielectric film on metal films 104, 204. Alternatively, at least one selected from a group consisting of Si₃N₄, Sc₂O₃, Zr₂O₃, Y₂O₃, Gd₂O₃, La₂O₃, Ta₂O₅, ZrO₂, LaAlO₃, ZrTiO₄ and HfO₂ may be employed therefor.

In the first and second embodiments, AlN was used to form intermediate layers 102, 202. Instead of AlN, a DBR (distributed Bragg reflection) layer of AlₓB_{y}In_{z}Ga_{1-x-y-z}N (0<x≦1, 0≦y<1, 0≦z≦1, x+y+z=1) may be employed, or both the AlN layer and the DBR layer thereon may also be employed.

In the third, fourth and fifth embodiments, metal films 307, 408 and 509 are not exposed to such a high temperature at the time of forming the nitride semiconductor layers as in the first and second embodiments. Thus, it is unnecessary to employ a metal having a high melting point of at least 900° C. A metal or a compound containing a metal attaining ohmic contact with the conductive Si substrate and the n type GaN layer will suffice.

In the first through fifth embodiments, active layers 107, 207, 304, 404, 505 may be formed to include a single or multiple quantum well layer. They may be non-doped or doped with Si, As or P. The well layers and barrier layers within the multiple quantum well layer may be formed with InGaN only, or using both InGaN and GaN.

In the first through fifth embodiments, the {111} Si substrates were used as conductive semiconductor substrates 101, 201, 301, 401, 501. The similar effects were obtained by employing a {100} Si substrate or a Si substrate having a main surface orientation slightly inclined with respect to a {111} plane or a {100} plane. Other conductive substrates such as a ZnO substrate and a GaP substrate may also be employed.

In the first through fifth embodiments, AlN was used to form intermediate layers 102, 202, 302, 402, 503. The same effect was obtained also by using AlₓB_{y}In_{z}Ga_{1-x-y-z}N (0<x≦1, 0≦y<1, 0≦z≦1, x+y+z=1).

In the first through fourth embodiments, trenches were formed each as a region for formation of a metal film connecting the AlₓB_{y}In_{z}Ga_{1-x-y-z}N (0<x≦1, 0≦y<1, 0≦z≦1, x+y+z=1) layer in contact with the intermediate layer to the conductive substrate. The trenches need not be formed along one direction. They may also be formed along at least two different directions.

As described above, according to the present invention, it is possible. to reduce an operating voltage of a nitride-based semiconductor light-emitting device having current-introducing electrodes formed on both main surface sides of a substrate.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nitride-based semiconductor light-emitting device, comprising:
a conductive semiconductor substrate having first and second main surfaces;
a high resistant or insulative intermediate layer formed on the first main surface of said substrate;
a plurality of nitride semiconductor layers of AlₓB_{y}In_{z}Ga_{1-x-y-z}N (0<x≦1, 0≦y<1, 0≦z≦1, x+y+z=1) formed on said intermediate layer, said plurality of nitride semiconductor layers including at least one first conductivity type layer, a light-emitting layer and at least one second conductivity type layer sequentially stacked on said intermediate layer;
a metal film penetrating through or detouring around said intermediate layer to connect said first conductivity type layer in contact with said intermediate layer to said conductive substrate;
a first electrode formed on said second conductivity type layer; and
a second electrode formed on the second main surface of said substrate;
wherein voltage drop in said intermediate layer is avoided by said metal film to reduce an operating voltage.

2. The nitride-based semiconductor light-emitting device according to claim 1, wherein AlₓB_{y}In_{z}Ga_{1-x-y-z}N (0<x≦1, 0≦y<1, 0≦z≦1, x+y+z=1) is used for said intermediate layer.

3. The nitride-based semiconductor light-emitting device according to claim 1, wherein said intermediate layer has a thickness of at least 10 nm.

4. The nitride-based semiconductor light-emitting device according to claim 1, wherein said metal film is in ohmic contact with said conductive substrate and said first conductivity type layer contacting said intermediate layer.

5. The nitride-based semiconductor light-emitting device according to claim 1, wherein said metal film has a melting point higher than 900° C.

6. The nitride-based semiconductor light-emitting device according to claim 1, wherein at least one selected from a group consisting of Sc, Ti, V, Cr, Mn, Cu, Y, Nb, Mo, Ru, Hf, Ta and W is used for said metal film.

7. The nitride-based semiconductor light-emitting device according to claim 1, further comprising a dielectric film for preventing said metal film from contacting said light-emitting layer and said second conductivity type layer.

8. The nitride-based semiconductor light-emitting device according to claim 7, wherein at least one selected from a group consisting of SiO₂, Si₃N₄, Sc₂O₃, Zr₂O₃, Y₂O₃, Gd₂O₃, La₂O₃, Ta₂O₅, ZrO₂, LaAlO₃, ZrTiO₄ and HfO₂ is used for said dielectric film.

9. The nitride-based semiconductor light-emitting device according to claim 1, wherein said metal film is formed in a stripe pattern, and said metal film stripes are arranged with an interval in a range from 1 μm to 500 μm.

10. The nitride-based semiconductor light-emitting device according to claim 9, wherein said metal film stripes are formed along one direction or along at least two different directions.

11. The nitride-based semiconductor light-emitting device according to claim 1, wherein said light-emitting layer is formed in a region partitioned by a partitioning stripe having a width of at least 1 μm formed on said substrate.

12. The nitride-based semiconductor light-emitting device according to claim 11, wherein a dielectric film is used as said partitioning stripe.

13. The nitride-based semiconductor light-emitting device according to claim 12, wherein at least one selected from a group consisting of SiO₂, Si₃N₄, Sc₂O₃, Zr₂O₃, Y₂O₃, Gd₂O₃, La₂O₃, Ta₂O₅, ZrO₂, LaAlO₃, ZrTiO₄ and HfO₂ is used for said dielectric film.

14. The nitride-based semiconductor light-emitting device according to claim 11, wherein at least one metal selected from a group consisting of Sc, Ti, V, Cr, Mn, Cu, Y, Nb, Mo, Ru, Hf, Ta and W is used for said partitioning stripe.

15. The nitride-based semiconductor light-emitting device according to claim 1, wherein Si, ZnO or GaP containing a dopant is used for said conductive semiconductor substrate.

16. A method for manufacturing the nitride-based semiconductor light-emitting device according to claim 1, comprising the steps of:
forming at least said intermediate layer on said conductive semiconductor substrate in a film-deposition system;
after taking out a wafer having said at least intermediate layer formed on said substrate temporarily to the atmosphere, forming an opening portion penetrating through said intermediate layer;
forming said metal film in said opening portion; and
after introducing said wafer back to said film-deposition system, forming said plurality of nitride semiconductor layers.

17. A method for manufacturing the nitride-based semiconductor light-emitting device according to claim 1, comprising the steps of:
forming said partitioning stripe on said substrate;
forming said intermediate layer;
forming said plurality of nitride semiconductor layers;
removing said partitioning stripe;
forming an insulating film for preventing said light-emitting layer and said second conductivity type layer from contacting said metal film; and
forming, through a side surface of said intermediate layer, said metal film connecting said first conductivity type layer to said conductive substrate.

18. A method for manufacturing the nitride-based semiconductor light-emitting device according to claim 1, comprising the steps of:
removing by first etching a portion of said conductive substrate utilizing said intermediate layer as an etching-stop layer;
removing by second etching a portion of said intermediate layer exposed by said first etching; and
forming said metal film connecting said first conductivity type layer to said conductive substrate via a region where said intermediate layer has been partly removed by said second etching.
